(19) United States
(12) Patent Application Publication
(10) Pub. No.: US 2018/0304297 A1
(43) Pub. Date: Oct. 25, 2018

(54) COATING HEAD AND COATING MACHINE

(71) Applicant: WUHAN CHINA STAR OPTOELECTRONICS TECHNOLOGY CO., LTD., Wuhan, Hubei (CN)

(72) Inventor: Qinghua DAN, Wuhan, Hubei (CN)

(21) Appl. No.: 15/566,880

(22) PCT Filed: May 18, 2017
(86) PCT No.: PCT/CN2017/084856

§ 371 Date: Oct. 16, 2017

(30) Foreign Application Priority Data
Apr. 24, 2017 (CN) 201710269221.2

(51) Int. Cl. B05C 5/02; G03F 7/16

(52) U.S. Cl. CPC B05C 5/0225; G03F 7/16

(57) ABSTRACT

A coating head and a coating machine are provided. The coating head includes a main body and a spray nozzle. Each of two sides of an inside of the main body is provided with a photoresist injecting tank, respectively. The spray nozzle is disposed under the main body, and the spray nozzle is connected to one side of the photoresist injecting tank. The coating head and the coating machine of the present disclosure can improve production output.

### FIELD OF THE INVENTION

The present disclosure relates to a technical field of liquid crystal displays, and more particularly to a coating head and a coating machine.

### BACKGROUND OF THE INVENTION

Liquid crystal display technology is more mature nowadays. Usually, a liquid crystal panel is manufactured by steps of: assembling a color filter substrate and an array substrate; injecting liquid crystals; cutting; and adding a circuit module process. Currently, color filters use low temperature poly-silicon (LTPS) technology in the field, and are manufactured by six processes (BM/R/G/B/OC/PS). Each of the processes includes operations of washing, coating, pre-baking, exposure, development, and post-baking. Because the primary materials of the six processes are all photoresist materials, quality of the color filter is directly influenced by coating quality of the photoresist.

Specifically, the coating operation adds the photoresist material onto a substrate using a coating machine. The coating machine uses a coating head as a photoresist output component. As shown in FIG. 1, a conventional coating head includes a main body 11, three tanks 12 disposed inside the main body 11, an exhaust port 13, two photoresist injecting ports 14, 15, and a spray nozzle 16.

Exterior photoresist material is injected into the three tanks 12 through the photoresist injecting ports 14, 15, and then it is pressed, outputted, and coated onto a glass substrate from the spray nozzle 16. Usually, during the coating operation, distance between the spray nozzle 16 and the glass substrate is 100 um. When the production line is idle or changing between different photoresists, the photoresist is necessarily being discharged from inside of the coating head, and then the inside of the head is washed and immersed for a while in a washing liquid, so as to avoid contamination from remaining photoresist. The process is called “discharging glue and immersing tube” (discharging glue for 40 min, and immersing tube for 120 min, generally). That is, changing the photoresist requires a long time, and production output and production line availability is substantially lowered.

If particles flow into the coating head from pipelines, or dust flows into the coating head from the air, the coating operation will not be even, so that hand washing is necessary. However, the hand washing operation is difficult, and requires a long time, so that the production output is lowed.

Hence, it is necessary to provide a coating head and a coating machine, so as to solve the problems existing in the conventional technologies.

### SUMMARY OF THE INVENTION

The object of the present disclosure is to provide a coating head and a coating machine which can improve the production output.

For solving the above-mentioned technical problems, the present disclosure provides a coating head, which comprises: a main body; and a spray nozzle disposed under the main body; wherein each of two sides of an inside of the main body is provided with a photoresist injecting tank, respectively; and the spray nozzle is connected to one side of the photoresist injecting tank; the coating head further includes a photoresist storage unit and a control device, wherein the photoresist storage unit is configured to provide a photoresist material; the photoresist storage unit is connected to the photoresist injecting tanks; the control device is connected to the spray nozzle; wherein the control device is configured to control the spray nozzle connected to the photoresist injecting tank on the other side, in response to the photoresist tank on an active side being inoperable.

The coating head of the present disclosure further includes two photoresist injecting ports; each of the photoresist injecting ports corresponds with one of the photoresist injecting tanks; and the photoresist storage unit is connected to the corresponding photoresist injecting tank by each of the photoresist injecting ports.

The coating head of the present disclosure further includes a three-way valve, and the three-way valve has an input end, a first output end, and a second output end, wherein the input end is connected to the photoresist storage unit; and the first output end is connected to one side of the photoresist injecting tank, and the second output end is connected to the other side of the photoresist injecting tank.

The coating head of the present disclosure further includes two exhaust ports and two photoresist injecting ports; each of the photoresist injecting tanks corresponds with one of the exhaust ports and one of the photoresist injecting ports; and the exhaust port and the photoresist injecting port are connected to the corresponding photoresist injecting tank, respectively.

In the coating head of the present disclosure, the photoresist injecting port includes a main photoresist injecting port and a sub photoresist injecting port, and an aperture of the main photoresist injecting port is greater than an aperture of the sub photoresist injecting port.

In the coating head of the present disclosure, the photoresist injecting tank includes three tanks arranged along a same direction and connected to each other.

In the coating head of the present disclosure, the photoresist injecting tanks are configured to be injected and permeated with a photoresist.

For solving the above-mentioned technical problems, the present disclosure provides a coating head, which comprises: a main body; and a spray nozzle disposed under the main body; wherein each of two sides of an inside of the main body is provided with a photoresist injecting tank, respectively; and the spray nozzle is connected to one side of the photoresist injecting tank.

The coating head of the present disclosure further includes a photoresist storage unit configured to provide a photoresist material, and the photoresist storage unit is connected to the photoresist injecting tanks.

The coating head of the present disclosure further includes two photoresist injecting ports; each of the photoresist injecting ports corresponds with one of the photoresist injecting tanks; and the photoresist storage unit is connected to the corresponding photoresist injecting tank by each of the photoresist injecting ports.

The coating head of the present disclosure further includes a three-way valve, and the three-way valve has an input end, a first output end, and a second output end, wherein the input end is connected to the photoresist storage unit; and the first output end is connected to one side of the photoresist injecting tank, and the second output end is connected to the other side of the photoresist injecting tank.

In the coating head of the present disclosure, the coating head further includes a control device, and the control device is connected to the spray nozzle, wherein the control device is configured to control the spray nozzle connected to the photoresist injecting tank on the other side, in response to the photoresist tank on an active side being inoperable.

In the coating head of the present disclosure, the coating head further includes two exhaust ports and two photoresist injecting ports; each of the photoresist injecting tanks corresponds with one of the exhaust ports and one of the photoresist injecting ports; and the exhaust port and the photoresist injecting port are connected to the corresponding photoresist injecting tank, respectively.

In the coating head of the present disclosure, the photoresist injecting port includes a main photoresist injecting port and a sub photoresist injecting port, and an aperture of the main photoresist injecting port is greater than an aperture of the sub photoresist injecting port.

In the coating head of the present disclosure, the photoresist injecting tank includes three tanks arranged along a same direction and connected to each other.

In the coating head of the present disclosure, the photoresist injecting tanks are configured to be injected and permeated with a photoresist.

The present disclosure further provides a coating machine, which comprises any one of the above-mentioned coating heads.

In the coating head and the coating machine of the present disclosure, because the photoresist injecting tanks are disposed on the two sides of the main body, when particles of a greater diameter fall into one side of the photoresist injecting tanks, or particles fall into a deep location, the production can be continually processed by the other side of the photoresist injecting tanks, so that the time needed for an exception process is shortened, and the production output is improved.

### DESCRIPTION OF THE DRAWINGS

FIG. 1 is a schematic structural view of a conventional coating head.

FIG. 2 is a schematic structural view of a coating head according to a first embodiment of the present disclosure.

FIG. 3 is a schematic structural view of a coating head according to a second embodiment of the present disclosure.

FIG. 4 is a schematic structural view of a coating head according to a third embodiment of the present disclosure.

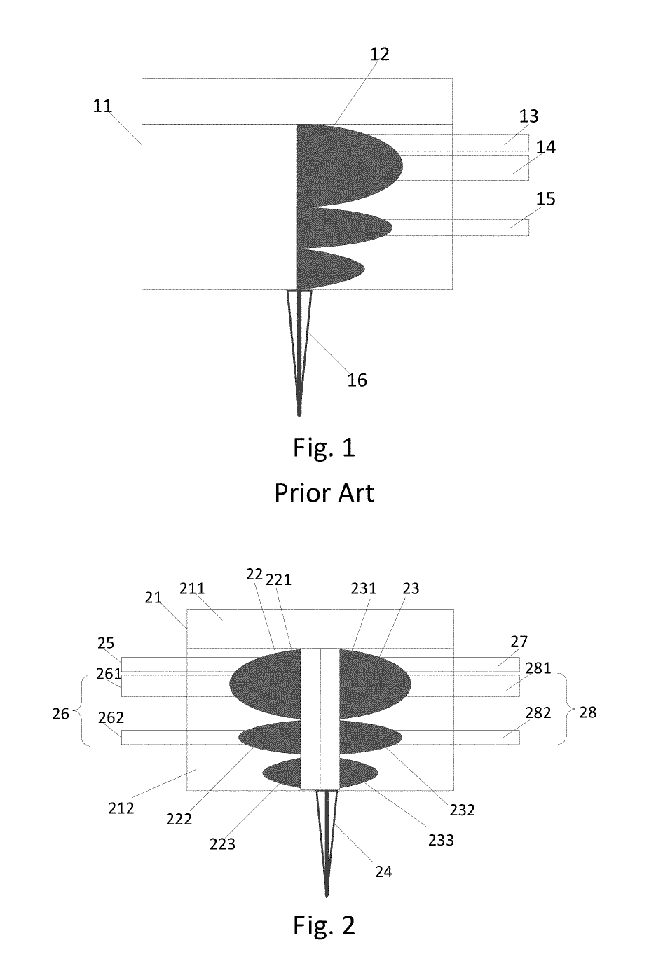

### DETAILED DESCRIPTION OF THE PREFERRED EMBODIMENTS

The foregoing objects, features, and advantages adopted by the present invention can be best understood by referring to the following detailed description of the preferred embodiments and the accompanying drawings. Furthermore, the directional terms described in the present invention, such as upper, lower, front, rear, left, right, inside, outer, side, etc., are only directions with reference to the accompanying drawings, so that the used directional terms are used to describe and understand the present invention, but the present invention is not limited thereto. In the drawings, units with similar structures use the same numerals.

Refer now to FIG. 2, which is a schematic structural view of a coating head according to the present disclosure.

As shown in FIG. 2, a coating head of the present disclosure includes a main body 21 and a spray nozzle 24, wherein the main body 21 has a top portion 211 and a bottom portion 212. In one embodiment, the material of the main body 21 is an alloy material, for example a hard alloy material. Two sides of an inside of the bottom portion 212 are provided with photoresist injecting tanks 22, 23, respectively, and the photoresist injecting tanks 22, 23 are configured to be injected and permeated for a photoresist. Each side of the photoresist injecting tank includes three tanks arranged along a same direction and connected to each other. In one embodiment, each side of the photoresist injecting tank includes three tanks connected to each other from top to bottom, wherein the left side of the photoresist injecting tank 22 has three tanks 221-223 connected to each other from top to bottom, and the right side of the photoresist injecting tank 23 has three tanks 231-233 connected to each other from top to bottom.

The spray nozzle 24 is disposed under the bottom portion 212, and the spray nozzle 24 is connected to one side of the photoresist injecting tank. In FIG. 2, the spray nozzle 24 is connected to the right side of the photoresist injecting tank 23.

The coating head further includes two exhaust ports 25, 27, and two photoresist injecting ports 26, 28. Each of the photoresist injecting tanks is correspondingly provided with one of the exhaust ports and one of the photoresist injecting ports. For example, the left side of the photoresist injecting tank 22 is correspondingly provided with the exhaust port 25 and the photoresist injecting port 26, and the exhaust port 25 and the photoresist injecting port 26 are connected to the photoresist injecting tank 22; and the right side of the photoresist injecting tank 23 is correspondingly provided with the exhaust port 27 and the photoresist injecting port 28, and the exhaust port 27 and the photoresist injecting port 28 are connected to the photoresist injecting tank 23.

Each of the photoresist injecting ports includes a main photoresist injecting port and a sub photoresist injecting port. The left side of the photoresist injecting port 26 includes a main photoresist injecting port 261 and a sub photoresist injecting port 262, and an aperture of the main photoresist injecting port 261 is greater than an aperture of the sub photoresist injecting port 262. The right side of the photoresist injecting port 28 includes a main photoresist injecting port 281 and a sub photoresist injecting port 282, and an aperture of the main photoresist injecting port 281 is greater than an aperture of the sub photoresist injecting port 282. Therefore, the coating operation is more even.

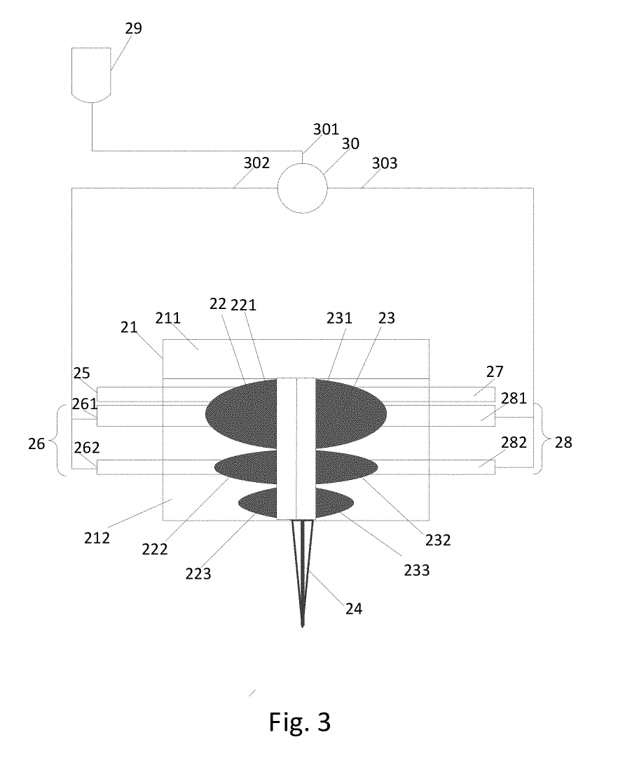

As shown in FIG. 3, the coating head further includes a photoresist storage unit 29 configured to provide a photoresist material, and the photoresist storage unit 29 is connected to the two sides of the photoresist injecting tanks 22, 23, wherein the photoresist storage unit 29 is connected to the each side of the photoresist injecting ports 26, 28. Specifically, the photoresist storage unit 29 is connected to the left side of the main photoresist injecting port 261 and the sub photoresist injecting port 262; and the photoresist storage unit 29 is connected to the right side of the main photoresist injecting port 281 and the sub photoresist injecting port 282. Because the photoresist injecting port 26 is connected to the photoresist injecting tank 22 and the photoresist injecting port 28 is connected to the photoresist injecting tank 23, the photoresist inside the photoresist storage unit 29 can flow into the photoresist injecting tank 22 or the photoresist injecting tank 23 through the photoresist injecting port 26 or the photoresist injecting port 28, so as to process a photoresist coating operation.

The coating head further includes a three-way valve 30, and the three-way valve 30 has an input end 301, a first output end 302, and a second output end 303, wherein the input end 301 is connected to the photoresist storage unit 29; the first output end 302 is connected to the left side of the photoresist injecting tank 22; and the second output end 303 is connected to the right side of the photoresist injecting tank 23. The first output end 302 is connected to the left side of the photoresist injecting port 26, and the second output end 303 is connected to the right side of the photoresist injecting port 28.

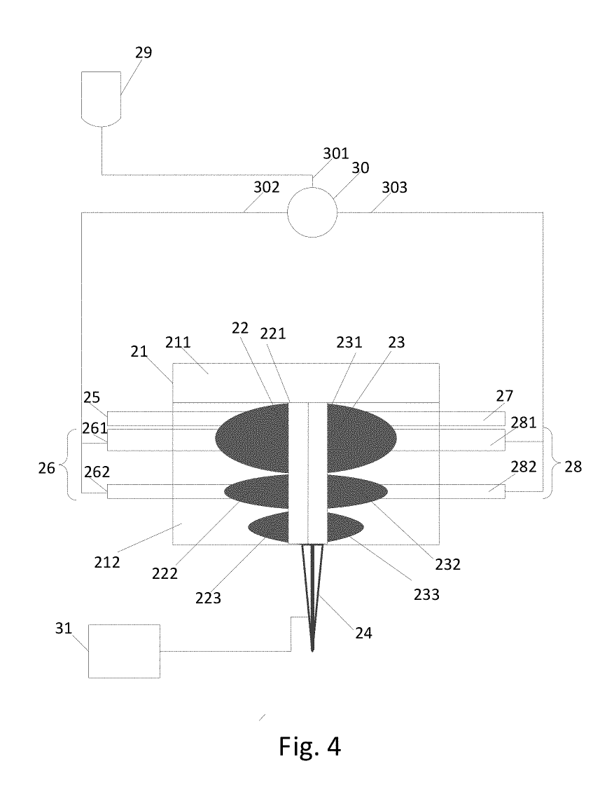

As shown in FIG. 4, the present disclosure further includes a control device 31, and the control device 31 is connected to the spray nozzle 24. When the photoresist injecting tank of an active side has an accident (is inoperable), the control device 31 is configured to control the spray nozzle 24 to connect to the photoresist injecting tank of the other side.

When in normal use, only one side of the photoresist injecting port and the photoresist injecting tank is used, and the other side of the photoresist injecting port and the photoresist injecting tank is in a clean and sealed condition. For example, when using the right side of the photoresist injecting tank, in a normal condition, the spray nozzle 24 is connected to the right side of the photoresist injecting tank 23, and controlled by the three-way valve 30, so that the photoresist inside the photoresist storage unit 29 is injected into the photoresist injecting tank 23 through the photoresist injecting port 28. If particles of a greater diameter fall into the right side of the photoresist injecting tank, or particles fall into a deep location, and they cannot be removed by a plastic scraper, the spray nozzle 24 can be moved from the right side to the left side by the control device 31, so as to connect the spray nozzle 24 and the photoresist injecting tank 22, and by a control of the three-way valve 30, the photoresist inside the photoresist storage unit 29 is injected into the photoresist injecting tank 22 through the left side of the photoresist injecting port 26.

Before connecting the spray nozzle 24 to the other side of the photoresist injecting tank, it is necessary to discharge the abnormal side of the photoresist and wash the inside with a wash liquid, and then move the spray nozzle 24. This can prevent the remaining photoresist in the abnormal side of the photoresist injecting tank from solidifying, and then the connecting location is sealed after a washing operation. The wash liquid can be a propylene glycol monomethyl ether acetate (PMA).

In the present disclosure, when particles fall into the inside causing abnormal quality, it is not necessary to disassemble and clean the inside of the coating head, so that the difficulty of an exception process is decreased, and the time needed for the exception process is shortened. Furthermore, because a two side photoresist injecting tanks design is provided, when changing the photoresist material, the photoresist material can be directly changed to the other side of the photoresist injecting tanks, so that a time needed for an immersing tube process is decreased, and the production output is improved. When one side of the coating head has an accident, it can be noted first, the production can be continually processed by the normal side of the photoresist injecting tank, and a repair operation can be processed after the production line is stopped, so as to improve the production output.

In the coating head of the present disclosure, because the photoresist injecting tanks are disposed on the two sides of the main body, when particles of a greater diameter fall into one side of the photoresist injecting tanks, or particles fall into a deep location, the production can be continually processed by the other side of the photoresist injecting tanks, so that the time needed for an exception process is shortened, and the production output is improved.

The present disclosure further provides a coating machine, which includes a coating head. As shown in FIG. 2, a coating head of the present disclosure includes a main body 21 and a spray nozzle 24, wherein the main body 21 has a top portion 211 and a bottom portion 212. In one embodiment, the material of the main body 21 is an alloy material, for example a hard alloy material. Two sides of an inside of the bottom portion 212 are provided with photoresist injecting tanks 22, 23, respectively, and the photoresist injecting tanks 22, 23 are configured to be injected and permeated for a photoresist. Each side of the photoresist injecting tank includes three tanks arranged along a same direction and connected to each other. In one embodiment, each side of the photoresist injecting tank includes three tanks connected to each other from top to bottom, wherein the left side of the photoresist injecting tank 22 has three tanks 221-223 connected to each other from top to bottom, and the right side of the photoresist injecting tank 23 has three tanks 231-233 connected to each other from top to bottom.

The spray nozzle 24 is disposed under the bottom portion 212, and the spray nozzle 24 is connected to one side of the photoresist injecting tank. In FIG. 2, the spray nozzle 24 is connected to the right side of the photoresist injecting tank 23.

The coating head further includes two exhaust ports 25, 27, and two photoresist injecting ports 26, 28. Each of the photoresist injecting tanks are correspondingly provided with one of the exhaust ports and one of the photoresist injecting ports. For example, the left side of the photoresist injecting tank 22 is correspondingly provided with the exhaust port 25 and the photoresist injecting port 26, and the exhaust port 25 and the photoresist injecting port 26 are connected to the photoresist injecting tank 22; and the right side of the photoresist injecting tank 23 is correspondingly provided with the exhaust port 27 and the photoresist injecting port 28, and the exhaust port 27 and the photoresist injecting port 28 are connected to the photoresist injecting tank 23.

Each of the photoresist injecting ports includes a main photoresist injecting port and a sub photoresist injecting port. The left side of the photoresist injecting port 26 includes a main photoresist injecting port 261 and a sub photoresist injecting port 262, and an aperture of the main photoresist injecting port 261 is greater than an aperture of the sub photoresist injecting port 262. The right side of the photoresist injecting port 28 includes a main photoresist injecting port 281 and a sub photoresist injecting port 282, and an aperture of the main photoresist injecting port 281 is greater than an aperture of the sub photoresist injecting port 282. Therefore, the coating operation is more even.

As shown in FIG. 3, the coating head further includes a photoresist storage unit 29 configured to provide a photoresist material, and the photoresist storage unit 29 is connected to the two sides of the photoresist injecting tanks 22, 23, wherein the photoresist storage unit 29 is connected to the each side of the photoresist injecting ports 26, 28. Specifically, the photoresist storage unit 29 is connected to the left side of the main photoresist injecting port 261 and the sub photoresist injecting port 262; and the photoresist storage unit 29 is connected to the right side of the main photoresist injecting port 281 and the sub photoresist injecting port 282. Because the photoresist injecting port 26 is connected to the photoresist injecting tank 22 and the photoresist injecting port 28 is connected to the photoresist injecting tank 23, the photoresist inside the photoresist storage unit 29 can flow into the photoresist injecting tank 22 or the photoresist injecting tank 23 through the photoresist injecting port 26 or the photoresist injecting port 28, so as to process a photoresist coating operation.

The coating head further includes a three-way valve 30, and the three-way valve 30 has an input end 301, a first output end 302, and a second output end 303, wherein the input end 301 is connected to the photoresist storage unit 29; the first output end 302 is connected to the left side of the photoresist injecting tank 22; and the second output end 303 is connected to the right side of the photoresist injecting tank 23. The first output end 302 is connected to the left side of the photoresist injecting port 26, and the second output end 303 is connected to the right side of the photoresist injecting port 28.

As shown in FIG. 4, the present disclosure further includes a control device 31, and the control device 31 is connected to the spray nozzle 24. When the photoresist injecting tank of an active side has an accident (is inoperable), the control device 31 is configured to control the spray nozzle 24 to connect to the photoresist injecting tank of the other side.

When in normal use, only one side of the photoresist injecting port and the photoresist injecting tank are used, and the other side of the photoresist injecting port and the photoresist injecting tank are in a clean and sealed condition. For example, when using the right side of the photoresist injecting tank, in a normal condition, the spray nozzle 24 is connected to the right side of the photoresist injecting tank 23, and controlled by the three-way valve 30, so that the photoresist inside the photoresist storage unit 29 is injected into the photoresist injecting tank 23 through the photoresist injecting port 28. If particles of a greater diameter fall into the right side of the photoresist injecting tank, or particles fall into a deep location, and they cannot be removed by a plastic scraper, the spray nozzle 24 can be move from the right side to the left side by the control device 31, so as to connect the spray nozzle 24 and the photoresist injecting tank 22, and by a control of the three-way valve 30, the photoresist inside the photoresist storage unit 29 is injected into the photoresist injecting tank 22 through the left side of the photoresist injecting port 26.

Before connecting the spray nozzle 24 to the other side of the photoresist injecting tank, it is necessary to discharge the abnormal side of the photoresist and wash the inside with a wash liquid, and then to move the spray nozzle 24. This can prevent the remaining photoresist in the abnormal side of the photoresist injecting tank from solidifying, and then the connecting location is sealed after a washing operation. The wash liquid can be a propylene glycol monomethyl ether acetate (PMA).

In the present disclosure, when particles fall into the inside causing abnormal quality, it is not necessary to disassemble and clean the inside of the coating head, so that the difficulty of an exception process is decreased, and the time needed for the exception process is shortened. Furthermore, because a two side photoresist injecting tanks design is provided, when changing the photoresist material, the photoresist material can be directly changed to the other side of the photoresist injecting tanks, so that the time needed for the immersing tube process is decreased, and the production output is improved. When one side of the coating head has an accident, it can be noted first, the production can be continually processed by the normal side of the photoresist injecting tank, and a repair operation can be processed after the production line is stopped, so as to improve the production output.

In the coating machine of the present disclosure, because the photoresist injecting tanks are disposed on the two sides of the main body, when particles of a greater diameter fall into one side of the photoresist injecting tanks, or particles fall into a deep location, the production can be continually processed by the other side of the photoresist injecting tanks, so that the time needed for an exception process is shortened, and the production output is improved.

The present disclosure has been described with preferred embodiments thereof and it is understood that many changes and modifications to the described embodiment can be carried out without departing from the scope and the spirit of the invention that is intended to be limited only by the appended claims.

What is claimed is:

1. A coating head, comprising:
a main body; and
a spray nozzle disposed under the main body;
wherein each of two sides of an inside of the main body is provided with a photoresist injecting tank, respectively; and the spray nozzle is connected to one side of the photoresist injecting tank; the coating head further includes a photoresist storage unit and a control device, wherein the photoresist storage unit is configured to provide a photoresist material; the photoresist storage unit is connected to the photoresist injecting tanks; the control device is connected to the spray nozzle; wherein the control device is configured to control the spray nozzle connected to the photoresist injecting tank on the other side, in response to the photoresist tank on an active side being inoperable.

2. The coating head according to claim 1, wherein the coating head further includes two photoresist injecting ports; each of the photoresist injecting ports corresponding to one of the photoresist injecting tanks; and the photoresist storage unit is connected to the corresponding photoresist injecting tank by each of the photoresist injecting ports.

3. The coating head according to claim 1, wherein the coating head further includes a three-way valve, and the three-way valve has an input end, a first output end, and a second output end, wherein the input end is connected to the photoresist storage unit; and the first output end is connected to one side of the photoresist injecting tank, and the second output end is connected to the other side of the photoresist injecting tank.

4. The coating head according to claim 1, wherein the coating head further includes two exhaust ports and two photoresist injecting ports; each of the photoresist injecting tanks corresponds with one of the exhaust ports and one of the photoresist injecting ports; and the exhaust port and the photoresist injecting port are connected to the corresponding photoresist injecting tank, respectively.

5. The coating head according to claim 4, wherein the photoresist injecting port includes a main photoresist injecting port and a sub photoresist injecting port, and an aperture of the main photoresist injecting port is greater than an aperture of the sub photoresist injecting port.

6. The coating head according to claim 1, wherein the photoresist injecting tank includes three tanks arranged along a same direction and connected to each other.

7. The coating head according to claim 1, wherein the photoresist injecting tanks are configured to be injected and permeated with a photoresist.

8. A coating head, comprising:
a main body; and
a spray nozzle disposed under the main body;
wherein each of two sides of an inside of the main body is provided with a photoresist injecting tank, respectively; and the spray nozzle is connected to one side of the photoresist injecting tank.

9. The coating head according to claim 8, wherein the coating head further includes a photoresist storage unit configured to provide a photoresist material, and the photoresist storage unit is connected to the photoresist injecting tanks.

10. The coating head according to claim 9, wherein the coating head further includes two photoresist injecting ports; each of the photoresist injecting ports corresponds with one of the photoresist injecting tanks; and the photoresist storage unit is connected to the corresponding photoresist injecting tank by each of the photoresist injecting ports.

11. The coating head according to claim 9, wherein the coating head further includes a three-way valve, and the three-way valve has an input end, a first output end, and a second output end, wherein the input end is connected to the photoresist storage unit; and the first output end is connected to one side of the photoresist injecting tank, and the second output end is connected to the other side of the photoresist injecting tank.

12. The coating head according to claim 8, wherein the coating head further includes a control device, and the control device is connected to the spray nozzle, wherein the control device is configured to control the spray nozzle connected to the photoresist injecting tank on the other side, in response to the photoresist tank on an active side being inoperable.

13. The coating head according to claim 8, wherein the coating head further includes two exhaust ports and two photoresist injecting ports; each of the photoresist injecting tanks corresponds with one of the exhaust ports and one of the photoresist injecting ports; and the exhaust port and the photoresist injecting port are connected to the corresponding photoresist injecting tank, respectively.

14. The coating head according to claim 13, wherein the photoresist injecting port includes a main photoresist injecting port and a sub photoresist injecting port, and an aperture of the main photoresist injecting port is greater than an aperture of the sub photoresist injecting port.

15. The coating head according to claim 8, wherein the photoresist injecting tank includes three tanks arranged along a same direction and connected to each other.

16. The coating head according to claim 8, wherein the photoresist injecting tanks are configured to be injected and permeated with a photoresist.

17. A coating machine, comprising a coating head, which comprises:
a main body; and
a spray nozzle disposed under the main body;
wherein each of two sides of an inside of the main body is provided with a photoresist injecting tank, respectively; and the spray nozzle is connected to one side of the photoresist injecting tank.

18. The coating machine according to claim 17, wherein the coating head further includes a photoresist storage unit configured to provide a photoresist material, and the photoresist storage unit is connected to the photoresist injecting tanks.

19. The coating machine according to claim 18, wherein the coating head further includes a three-way valve, and the three-way valve has an input end, a first output end, and a second output end, wherein the input end is connected to the photoresist storage unit; and the first output end is connected to one side of the photoresist injecting tank, and the second output end is connected to the other side of the photoresist injecting tank.

20. The coating machine according to claim 17, wherein the coating head further includes a control device, and the control device is connected to the spray nozzle, wherein the control device is configured to control the spray nozzle connected to the photoresist injecting tank on the other side, in response to the photoresist tank on an active side being inoperable.
